(19) United States
(12) Patent Application Publication
(10) Pub. No.: US 2023/0063808 A1
(43) Pub. Date: Mar. 2, 2023

(54) COAXIAL VIA SHIELDED INTERPOSER

(71) Applicant: Apple Inc., Cupertino, CA (US)

(72) Inventors: Nima Shahidi, San Francisco, CA (US); Meng Chi Lee, Los Altos, CA (US)

(21) Appl. No.: 17/465,596

(22) Filed: Sep. 2, 2021

(51) Int. Cl. H05K 1/02; H01L 23/498; H05K 1/14; H05K 3/00; H05K 3/42; H01L 21/48

(52) U.S. Cl. CPC H05K 1/0222; H01L 23/49827; H05K 1/145; H05K 3/0032; H05K 3/0047; H05K 3/426; H05K 3/0094; H01L 21/486; H05K 2201/10378; H05K 2201/0959

(57) ABSTRACT

A coaxial interposer may shield certain signals (e.g., noisy signals, high speed signals, radio frequency (RF) signals) transmitted through an electronic device. The coaxial interposer may include a coaxial via that includes an outer barrel of non-conductive material and an inner barrel of non-conductive material separated by a conductive barrel. Further, the outer barrel of non-conductive material may be enclosed by an outer metal coating. The coaxial via serves to internally shield each signals transmitted between layers of a printed circuit board (PCB) within the electronic device.

### BACKGROUND

The present disclosure relates generally to multi-layered boards and, more particularly, to efficiently shielding signals transmitted through an interposer associated with a multi-layered board.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Multi-layered boards such as printed circuit boards (PCBs) are used to mechanically support and electrically connect electrical components within electronic devices. For example, such electronic devices may include computers, mobile phones, portable media devices, tablets, televisions, virtual-reality headsets, and vehicle dashboards, among many others. Printed circuit boards (PCBs) may include an interposer that serves as a multi-layer conduit (e.g., communication channel) for transferring, electrical signals between at least two layers (e.g., interposer between a top layer and a bottom layer of the printer circuit board (PCB) or interposer between application board and radio frequency (RF) board). In some cases, noisy signals or high speed signals may emit electromagnetic radiation that causes cross-talk and signal interference between layers of interposer. To prevent cross-talk, such noisy or high speed signals may be shielded with grounded pins that are similar in structure as the signal pins or noisy power pins. Additionally, edge plating (e.g., applying a metal coating to the perimeter edges of the interposer) may be used to shield noisy or high speed signals. However, such shielding techniques may not effectively shield signals nor be cost effective. Further, edge plating may increase the size of the interposer, and thereby reduce the amount of space allocated for including additional functionalities or structures in an electronic device.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

A printed circuit board (PCB) may have a number of metal and core (e.g., non-conductive, dielectric) layers. In some embodiments, the metal layers may be composed of copper, aluminum, or any suitable metal, and the core layers may be composed resin, fiberglass, or any suitable core material. The core layer may be non-conductive and serve as an electric insulator to prevent layer to layer shorts in the printed circuit board (PCB). For example, resin impregnated fiber glass may be disposed between two copper layers. Pre-impregnated (pre-preg) composite fibers or materials are made of a polymer matrix reinforced with glass fibers sheet and may be used to provide electrical insulation. Additionally, an interposer may connect a top layer of the printed circuit board (PCB) to a bottom layer. For example, the interposer may serve as a conduit for transferring electrical signal between a top board (e.g., application processor board) and a bottom board (e.g., radio frequency board) of an electronic device.

As mentioned above, noisy signals or high speed signals may cause cross-talk and signal interference between layers of an interposer and thereby printed circuit board (PCB). To prevent cross-talk, such noisy or high speed signals may be shielded with grounded pins that are similar in structure as the signal pins or noisy power pins. Additionally, edge plating (e.g., applying a metal coating to the perimeter edges of the interposer) may be used to shield noisy or high speed signals. However, such shielding techniques may not effectively shield signals nor be cost effective. Further, edge plating may increase the size of the interposer, and thereby reduce the amount of space allocated for including additional functionalities or structures in an electronic device.

It may be desirable to effectively shield electrical signals without increasing the overall thickness of the interposer and without increasing the cost for manufacturing the interposer. Further, because manufacturing a thin interposer therefore a thin printed circuit board (PCB) may provide space for additional functionalities in electronic devices, improved features or techniques for manufacturing a coaxial shielded interposer may be desirable to electronic device manufacturers. Accordingly, the present disclosure provides techniques for manufacturing the coaxial shielded interposer.

The coaxial shielded interposer includes a coaxial via that internally shiels each signal transmitted through the layers of a printed circuit board (PCB). As used herein, a via is a communication channel of passageway within an interposer. For example, the coaxial via may shield internally shield each radio frequency (RF) signal transmitted between an application board and a radio frequency (RF) board of the printed circuit board (PCB). The coaxial via may include an outer barrel of non-conductive material and an inner barrel of non-conductive material that are separated by a conductive barrel, which serves as a signal carrier. That is, the inner barrel of non-conductive material may be fully enclosed by the conductive barrel, and the conductive barrel may be fully enclosed by the outer barrel of non-conductive material. Further, the outer barrel of non-conductive material 84 may be fully enclosed by a metal coating (e.g., outer metal coating). Together, the outer metal coating, the outer barrel of non-conductive material, the conductive barrel, and the inner barrel of non-conductive material form the coaxial via that serves to internally shield signals transmitted through the printed circuit board (PCB).

It can be appreciated that internally shielding each signal via the coaxial via reduces cross-talk and is cost effective compared to shielding techniques that include edge plating. As mentioned above, edge plating involves coating perimeter edges of an interposer with a metal or conductive material. While edge plating, as a whole, may externally shield signals transmitted through the interposer, edge plating does not internally shield each signal transmitted through the interposer. By internally shielding induvial signals, cross-talk between layers in the coaxial interposer may be reduce to a greater extent compared to an interposer without the coaxial via or with only edge plating. Further, even with electronic device having the coaxial interposer, space for additional structures and functionalities (e.g., larger battery) in the electronic device may be available.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a block diagram of an electronic device with an electronic display, in accordance with an embodiment of the present disclosure;

FIG. 2 is an example of the electronic device of FIG. 1, in accordance with an embodiment of the present disclosure;

FIG. 3 is another example of the electronic device of FIG. 1, in accordance with an embodiment of the present disclosure;

FIG. 4 is another example of the electronic device of FIG. 1, in accordance with an embodiment of the present disclosure;

FIG. 5 is another example of the electronic device of FIG. 1, in accordance with an embodiment of the present disclosure;

FIG. 6 is a schematic illustration of hardware components (e.g., coaxial interposer, multi-layered board) of the electronic device of FIG. 1, in accordance with an embodiment of the present disclosure;

FIG. 7 is a schematic illustration depicting a detailed view of coaxial interposer of the electronic device of FIG. 1, in accordance with an embodiment of the present disclosure;

FIG. 8 is a cross section of the coaxial interposer of FIG. 7, in accordance with an embodiment of the present disclosure;

FIG. 9 is a flow diagram of a process for manufacturing the coaxial interposer of FIG. 7, in accordance with an embodiment of the present disclosure; and

FIG. 10 is a schematic illustration of the coaxial interposer of FIG. 7 with a through hole and another coaxial interposer with a blind via, in accordance with an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions are made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

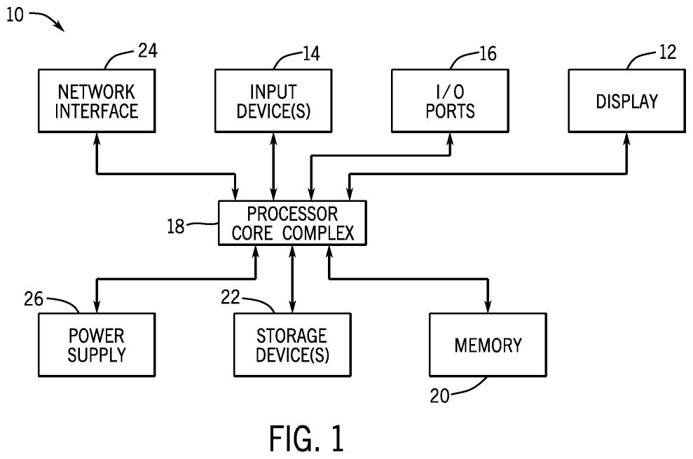

With the preceding in mind and to help illustrate, an electronic device 10 including an electronic display 12 is shown in FIG. 1. As is described in more detail below, the electronic device 10 may be any suitable electronic device, such as a computer, a mobile phone, a portable media device, a tablet, a television, a virtual-reality headset, a vehicle dashboard, and the like. Thus, it should be noted that FIG. 1 is merely one example of a particular implementation and is intended to illustrate the types of components that may be present in an electronic device 10.

The electronic display 12 may be any suitable electronic display. For example, the electronic display 12 may include a self-emissive pixel array having an array of one or more of self-emissive display pixels. The electronic display 12 may include any suitable circuitry to drive the self-emissive display pixels, including for example row driver or column drivers (e.g., display drivers). The self-emissive display pixels may include any suitable light emitting element, such as an LED, one example of which is an OLED. However, any other suitable type of display pixel, including non-self-emissive display pixels (e.g., liquid crystal as used in liquid crystal displays (LCDs), digital micromirror devices (DMD) used in DMD displays) may also be used.

The electronic device 10 includes the electronic display 12, one or more input devices 14, one or more input/output (I/O) ports 16, a processor core complex 18 having one or more processor(s) or processor cores, local memory 20, a main memory storage device 22, a network interface 24, and a power source 26 (e.g., power supply). The various components described in FIG. 1 may include hardware elements (e.g., circuitry), software elements (e.g., a tangible, non-transitory computer-readable medium storing executable instructions), or a combination of both hardware and software elements. It should be noted that the various depicted components may be combined into fewer components or separated into additional components. For example, the local memory 20 and the main memory storage device 22 may be included in a single component.

In some embodiments, the processor core complex 18 may include imaging processing circuitry to process image data based at least in part on compensation parameters (e.g., compensation mask) before processed pixel data is used to display corresponding image content on the electronic display 12. To compensate for defective display pixels (e.g., partially or fully dark display pixels), the image processing circuity may process pixel data based on a compensation mask.

The processor core complex 18 is operably coupled with local memory 20 and the main memory storage device 22. Thus, the processor core complex 18 may execute instruction stored in local memory 20 or the main memory storage device 22 to perform operations, such as generating or transmitting image data. As such, the processor core complex 18 may include one or more general purpose microprocessors, one or more application specific integrated circuits (ASICs), one or more field programmable logic arrays (FPGAs), or any combination thereof.

In addition to instructions, the local memory 20 or the main memory storage device 22 may store data to be processed by the processor core complex 18. Thus, the local memory 20 and/or the main memory storage device 22 may include one or more tangible, non-transitory, computer-readable media. For example, the local memory 20 may include random access memory (RAM) and the main memory storage device 22 may include read-only memory (ROM), rewritable non-volatile memory such as flash memory, hard drives, optical discs, or the like.

The network interface 24 may communicate data with another electronic device or a network. For example, the network interface 24 (e.g., a radio frequency system) may enable the electronic device 10 to communicatively couple to a personal area network (PAN), such as a Bluetooth network, a local area network (LAN), such as an 802.11x Wi-Fi network, or a wide area network (WAN), such as a 4G, Long-Term Evolution (LTE), or 5G cellular network. The power source 26 may provide electrical power to one or more components in the electronic device 10, such as the processor core complex 18 or the electronic display 12. Thus, the power source 26 may include any suitable source of energy, such as a rechargeable lithium polymer (Li-poly) battery or an alternating current (AC) power converter. The I/O ports 16 may enable the electronic device 10 to interface with other electronic devices. For example, when a portable storage device is connected, the I/O port 16 may enable the processor core complex 18 to communicate data with the portable storage device. The input devices 14 may enable user interaction with the electronic device 10, for example, by receiving user inputs via a button, a keyboard, a mouse, a trackpad, or the like. The input device 14 may include touch-sensing components in the electronic display 12. The touch sensing components may receive user inputs by detecting occurrence or position of an object touching the surface of the electronic display 12.

In addition to enabling user inputs, the electronic display 12 may include a display panel with one or more display pixels. The electronic display 12 may control light emission from the display pixels to present visual representations of information, such as a graphical user interface (GUI) of an operating system, an application interface, a still image, or video content, by displaying frames of image data. To display images, the electronic display 12 may include display pixels implemented on the display panel. In some embodiments, the display pixels may represent sub-pixels that each control a luminance of one color component (e.g., red, green, or blue for an RGB pixel arrangement or red, green, blue, or white for an RGBW arrangement).

The electronic display 12 may display an image by controlling light emission from its display pixels based on pixel or image data associated with corresponding image pixels (e.g., points) in the image. In some embodiments, pixel or image data may be generated by an image source, such as the processor core complex 18, a graphics processing unit (GPU), or an image sensor. Additionally, in some embodiments, image or pixel data may be received from another electronic device 10, for example, via the network interface 24 and/or an I/O port 16. Similarly, the electronic display 12 may display frames based on pixel or image data generated by the processor core complex 18, or the electronic display 12 may display frames based on pixel or image data received via the network interface 24, an input device, or an I/O port 16.

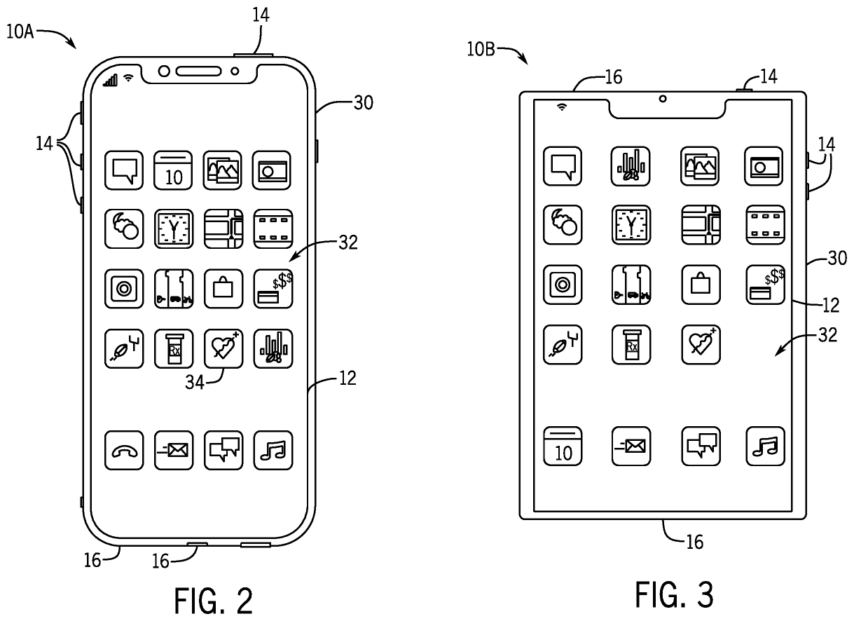

The electronic device 10 may be any suitable electronic device. To help illustrate, an example of the electronic device 10, a handheld device 10A, is shown in FIG. 2. The handheld device 10A may be a portable phone, a media player, a personal data organizer, a handheld game platform, or the like. For illustrative purposes, the handheld device 10A may be a smart phone, such as any IPHONE® model available from Apple Inc.

The handheld device 10A includes an enclosure 30 (e.g., housing). The enclosure 30 may protect interior components from physical damage or shield them from electromagnetic interference, such as by surrounding the electronic display 12. The electronic display 12 may display a graphical user interface (GUI) 32 having an array of icons. When an icon 34 is selected either by an input device 14 or a touch-sensing component of the electronic display 12, an application program may launch.

The input devices 14 may be accessed through openings in the enclosure 30. The input devices 14 may enable a user to interact with the handheld device 10A. For example, the input devices 14 may enable the user to activate or deactivate the handheld device 10A, navigate a user interface to a home screen, navigate a user interface to a user-configurable application screen, activate a voice-recognition feature, provide volume control, or toggle between vibrate and ring modes.

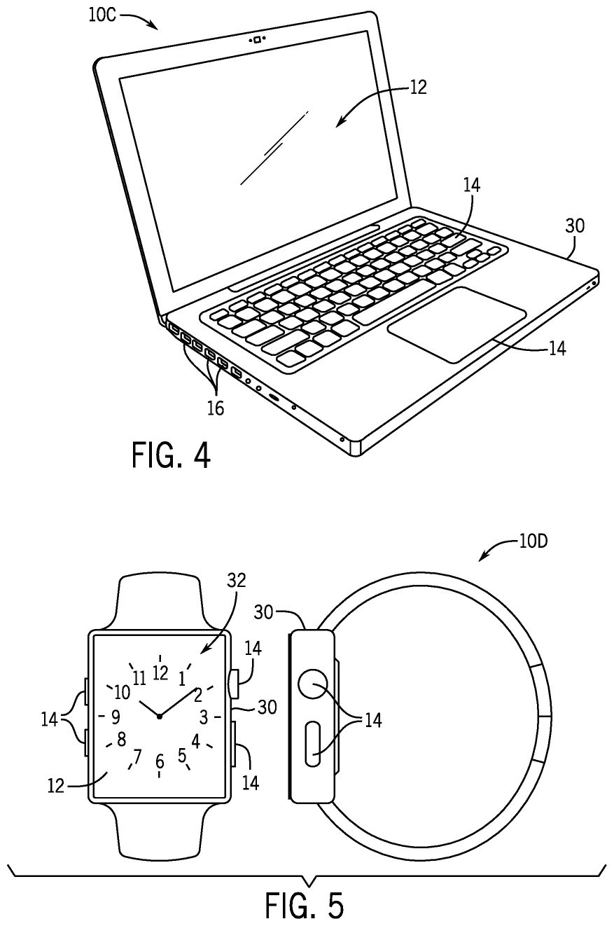

Another example of a suitable electronic device 10, specifically a tablet device 10B, is shown in FIG. 3. The tablet device 10B may be any IPAD® model available from Apple Inc. A further example of a suitable electronic device 10, specifically a computer 10C, is shown in FIG. 4. For illustrative purposes, the computer 10C may be any MACBOOK® or IMAC® model available from Apple Inc. Another example of a suitable electronic device 10, specifically a watch 10D, is shown in FIG. 5. For illustrative purposes, the watch 10D may be any APPLE WATCH® model available from Apple Inc. As depicted, the tablet device 10B, the computer 10C, and the watch 10D each also includes an electronic display 12, input devices 14, I/O ports 16, and an enclosure 30. The electronic display 12 may display a GUI 32. Here, the GUI 32 shows a visualization of a clock. When the visualization is selected either by the input device 14 or a touch-sensing component of the electronic display 12, an application program may launch, such as to transition the GUI 32 to presenting the icons 34 discussed in FIGS. 2 and 3.

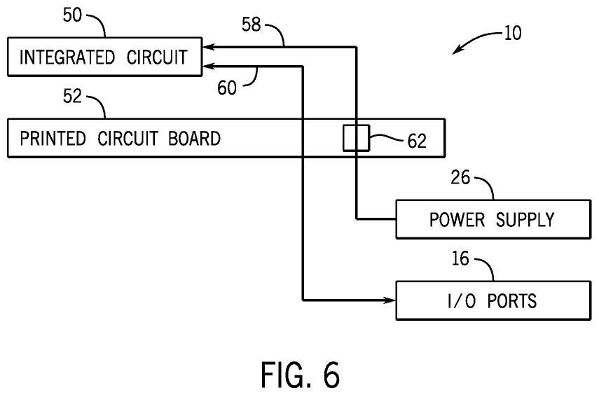

With the foregoing in mind, FIG. 6 is schematic illustration of hardware components (e.g., multi-layered board) within the electronic device 10, in accordance with an embodiment of the present disclosure. An integrated circuit 50, a printed circuit board (PCB) 52, a power supply 54, and I/O ports 16 may each be communicatively coupled to directly or indirectly (e.g., through or via another component, a communication bus, a network) to one another to transmit and/or receive electrical signals between one another. It should be noted that FIG. 6 is merely one example of a particular implementation and is intended to illustrate the types of components that may be present in electronic device 10.

The integrated circuit 50, an electronic circuit formed on a small piece of semiconducting material, may function as an amplifier, an oscillator, a timer, a microprocessor, a computer memory, and so forth. The printed circuit board (PCB) 52 is composed of layers of metal (e.g., copper) and non-conductive substrate (e.g., resin) mechanically supports and electrically connects electronic components (e.g., connects the integrated circuit 50 to the power supply 54 and the I/O ports 16). The power supply 54 of the electronic device 10 may include any suitable source of power, such as a rechargeable lithium polymer (Li-poly) battery and/or an alternating current (AC) power converter. The I/O ports 16 may enable the electronic device 10 to interface with various other electronic devices. In some embodiments, the I/O interface 24 may include an I/O port for a hardwired connection for charging and/or content manipulation using a standard connector and protocol, such as the Lightning connector provided by Apple Inc. of Cupertino, Calif., a universal serial bus (USB), or other similar connector and protocol.

As illustrated in FIG. 6, an electrical signal 60 may be transferred between the integrated circuit 50 and the I/O ports 16. Similarly, a power signal 58 may be transferred from the power supply 54 to the integrated circuit 50. As mentioned above, certain signals (e.g., radio frequency signals, noisy signals, high speed signals) may emit electromagnetic radiation that causes cross-talk and signal interference between layers of the printed circuit board (PCB) 52. To prevent cross-talk, each signal transmitted through the printed circuit board (PCB) 52 and between components of the electronic device 10 may be shielded via a coaxial interposer 62. The coaxial interposer 62 may be disposed between a top (e.g., first) board and a bottom (e.g., second) board of the printed circuit board (PCB) 52. For example, the coaxial interposer may shield a radio frequency (RF) signal transmitted between an application board and a radio frequency board of the printed circuit board (PCB) 52.

As illustrated, the coaxial interposer 62 may shield the power signal 58 transmitted from the power supply to the integrated circuit 50. In additional and/or alternative embodiments, another coaxial interposer (e.g., separate from the coaxial interposer 62) may shield the electrical signal 60 transmitted between the I/O ports 16 and the integrated circuit 50. That is, each signal may be separately shielded via a respective coaxial interposers 62. Further, the coaxial interposer 62 and the printed circuit board (PCB) 52 may each include any number of conductive layers (e.g., copper layers) and any number of non-conductive layers (e.g., core layers, resin layers).

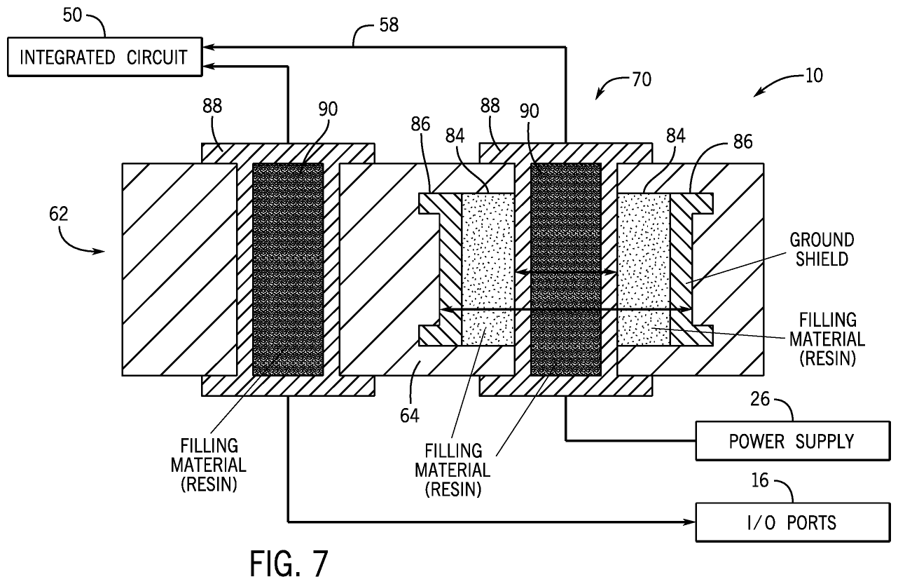

FIG. 7 is a detailed view of the coaxial interposer 62 that serves to shield certain signals (e.g., power signals, high speed signals, radio frequency (RF) signals) to prevent cross-talk between interior layers the printed circuit board (PCB) 52, in accordance with an embodiment of the present disclosure. As defined here, a coaxial interposer 62 is a multi-layer interface 64 with a coaxial via 70 (e.g., a communication channel with at least two concentric materials that share a common axis) for transferring electrical signals between at least two layers of the printed circuit board (PCB) 52. The multi-layer interface 64 may include any suitable number of metal layers and any suitable number of conductive layers. For example, the multi-layer interface 64 may include a multi-layer core, such as a two-layer core.

The coaxial via 70 of the coaxial interposer 62 may include an outer barrel of non-conductive material 84 and an inner barrel of non-conductive material 90 that are separated by a conductive barrel 88, which serves as a signal carrier. That is, the inner barrel of non-conductive material 90 may be fully enclosed by the conductive barrel 88, and the conductive barrel 88 may be fully enclosed by the outer barrel of non-conductive material 84. Further, the outer barrel of non-conductive material 84 may be fully enclosed by an outer metal coating 86. The outer metal coating 86 may serve as a ground shield.

Together, the outer metal coating 86, the outer barrel of non-conductive material 84, the conductive barrel 88, and the inner barrel of non-conductive material 90 form the coaxial via 70 that serves to internally shield signals transmitted through the printed circuit board (PCB) 52. It can be appreciated that internally shielding each signal via the coaxial via 70 reduces cross-talk and is cost effective compared to shielding techniques that include edge plating. As mentioned above, edge plating involves coating perimeter edges of an interposer with a metal or conductive material. While edge plating, as a whole, may externally shield signals transmitted through the interposer, edge plating does not internally shield each signal transmitted through the interposer. By internally shielding induvial signals, cross-talk between layers in the coaxial interposer 62 may be reduce to a greater extent compared to an interposer without the coaxial via 70 or with only edge plating.

Further, by adding a metal coating to the perimeter of the interposer, edge plating increases the thickness of the overall thickness interposer. For example, a copper coating with a thickness between 10 and 40 μm may be applied to external edges of the interposer. A thicker interposer may not be cost-effective and may limit the amount of available space in the electronic device 10 for additional components and features. Even with the coaxial via 70, the thickness of an interposer remains constant. As later described in detail, to manufacture the coaxial via 70, one or more holes may be drilled into the multi-layer core 64 of the coaxial interposer 62. For example, a hole may be filled with filling material (e.g., resin) to form the outer barrel of non-conductive material 84. Another hole may be drilled into the resin-filled hole. Metal may be poured and laminated in the other hole or a wire may be run through the other hole to form the conductive barrel 88. As such, to create the coaxial via 70, existing layers of an interposer are drilled to create holes and subsequently filled with material for internally shielding each signal. As such, the coaxial interposer 62 may be thinner than an interposer with an additional metal coating (e.g., edge plating). As such, even with electronic device having the coaxial interposer 62, space for additional structures and functionalities (e.g., larger battery) in the electronic device 10 may be available.

In some embodiments, the outer barrel of non-conductive material 84 and the inner barrel of non-conductive material 90 may be composed of filling material such as resin (e.g., thermosetting resin, thermoplastic resin), pre-impregnated (pre-preg) composite fibers, materials with a polymer matrix reinforced with glass fibers, and the like. The outer metal coating 86 and the conductive barrel 88 may be composed of copper, silver, nickel, or any suitable metal.

The outer barrel of non-conductive material 84 and the inner barrel of non-conductive material 90 may be composed of similar types of filling material (e.g., resin). In other embodiments, the outer barrel of non-conductive material 84 and the inner barrel of non-conductive material 90 may be composed of different types of filling material (e.g., resin). That is, the outer barrel of non-conductive material 84 and the inner barrel of non-conductive material 90 may vary in terms of dielectric properties, mechanical properties, and the like. For example, the inner barrel may be composed of thermosetting resin while the outer barrel may be composed of thermoplastic resin.

The outer metal coating 86 and the outer barrel of non-conductive material 84 may have a diameter of 300 μm, 450 μm, 600 μm, and the like. The conductive barrel 88 and the inner barrel of non-conductive material may have a diameter of 150 μm, 250 μm, 350 μm, and the like. Further, the outer barrel of non-conductive material 84, the inner barrel of non-conductive material 90, or both may have a dielectric constant between 2 and 3. Further, the coaxial interposer 62 may have loss tangent of 0.001, and impedance across the length of the coaxial interposer 62 may remain constant.

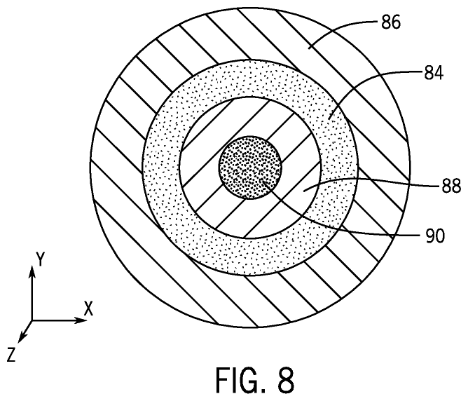

While FIG. 7 depicted a side view of the coaxial interposer 62, FIG. 8 is a cross-section of the coaxial via 70, in accordance with an embodiment of the present disclosure. As illustrated in FIG. 8, the outer barrel of non-conductive material 84 and the inner barrel of non-conductive material 90 are separated by a conductive barrel (e.g., conductive signal carrier) 88. That is, the inner barrel of non-conductive material 90 is fully enclosed by the conductive barrel 88, and the conductive barrel 88 is fully enclosed by the outer barrel of non-conductive material 84. Further, the outer barrel of non-conductive material 84 is fully enclosed by the outer metal coating 86.

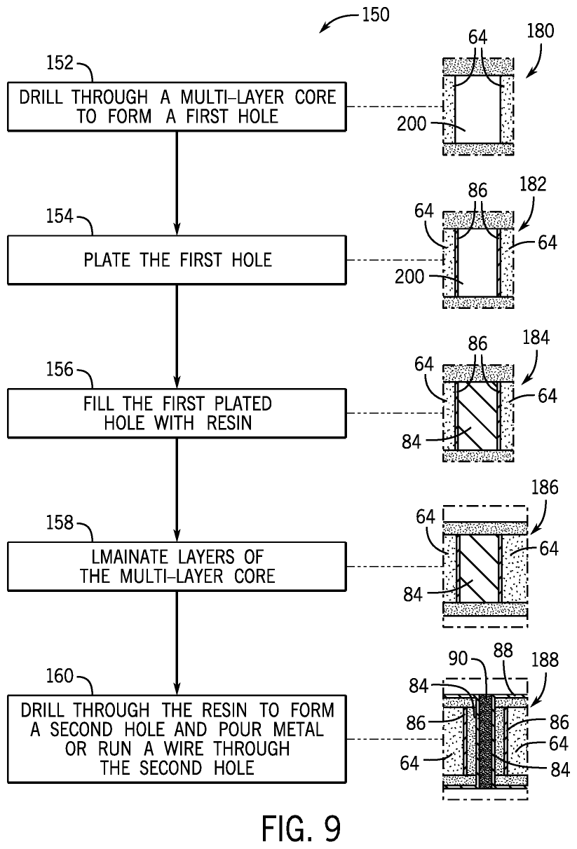

With the preceding in mind, FIG. 9 is a flow chart of process 150 for manufacturing a coaxial interposer, in accordance with an embodiment of the present disclosure. While the process 150 is described using steps in a specific sequence, it should be understood that the present disclosure contemplates that the described steps may be performed in different sequences than the sequence illustrated, and certain described steps may be skipped or not performed altogether. As mentioned above, the interposer may include any number of metal layers and core layers. As used herein, the core layers may include any suitable dielectric (e.g., non-conductive) material such as fiber glass and resin. At block 152, a mechanical drill or a laser is used to drill a hole through a multi-layer core (e.g., two-layer core) of an interposer to form a hole. As illustrated, in some embodiments, the hole may be a through hole, which completely passes through the multi-layer core. For example, image 180 depicts a hole 200 between two-layer core 64.

At block 154, the process 150 involves plating the hole 200. Plating involves covering the surface or walls of the hole 200 with copper or any suitable conductive material to provide electrical conductivity. As depicted by image 182, the surface of the hole 200 is coated with a metal plating (e.g., copper plating) 86, resulting in a plated hole

At block 156, the plated hole is filled with resin or any suitable filling material (e.g., non-conductive material). As such, image 184 depicts a resin-filled hole 84 coated with the metal plating 86. For example, the filling material (e.g., non-conductive material) may include thermosetting resin such as epoxy, thermoplastic resin, and the like. Non-limiting examples of thermosetting resin include polyphenylene oxide-based resins, bismaleimide triazine-based resins, polyphenylene ether-based resins, polyimide-based resins. Further, non-limiting examples of thermoplastic resins include liquid crystalline polymer, polyether ether ketone.

At block 158, layers of the multi-layer core 64 are laminated. As such, image 186 depicts laminated layers of the multi-layer core 64. A hot press or any suitable machine (e.g., lamination machine) may be used to laminate the layers of the multi-layer core 64 such that the layers are partially or fully-cross linked (e.g., cured, hardened).

At block 160, a mechanical drill or a laser is used to drill another hole through the resin-filled hole 84 (also referred to as the outer barrel of non-conductive material 84 and the inner barrel of non-conductive material 90). In some embodiments, metal such as copper is poured into the other hole, and the metal in the other hole is laminated to form the conductive barrel (e.g., signal carrier) 88. In other embodiments, a wire is run through the other hole to form the conductive barrel 88. As such, image 188 depicts the conductive barrel 88 disposed between resin. A portion of the resin that encloses the conductive barrel 88 is referred to as the outer barrel of non-conductive material 84, and a portion of the resin that is enclosed by the conductive barrel 88 is referred to as the inner barrel of non-conductive material 84. Together, the outer metal coating 86, the outer barrel of non-conductive material 84, the conductive barrel 88, and the inner barrel of non-conductive material 90 form the coaxial via 70 that serves to shield internally signals transmitted through the coaxial interposer 62 and the printed circuit board (PCB) 52.

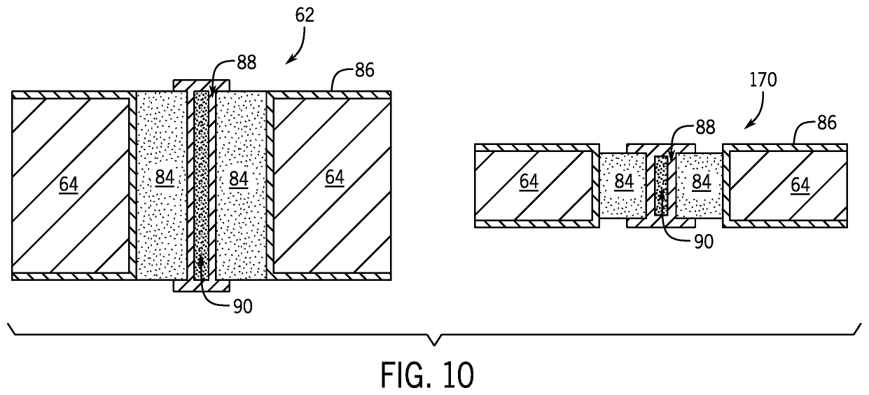

As mentioned above, in some embodiments, to form the coaxial via 70, a mechanical drill or laser may form through holes in the multi-layer core 64. The coaxial interposer 62 depicted in FIGS. 7 and 8 is formed based on drilling through holes in the multi-layer core 64. In other embodiments, a mechanical drill or laser may form blind vias in the multi-layer core 64 to form the coaxial via 70. As such, FIG. 10 depicts the coaxial interposer 62 with one or more through holes (e.g., through hole, coaxial interposer) and another interposer with blind vias (e.g., blind via coaxial interposer 170). As used herein, a though hole completely passes through a layer while a blind via partially passes through a layer. As such, a through hole in the coaxial interposer 62 completely passes through each of the layers of the multi-layer core 64. On the other hand, a blind via may only be exposed to one side of an interposer. That is, the blind via passes through a portion of the layers of the multi-layer core 64. However, both the through hole, coaxial interposer 62 and the blind via, coaxial interposer 170 may help internally shield each signal (e.g., noisy signal, high speed signal, radio frequency (RF) signal) transmitted through the layers of the printed circuit board (PCB) 52.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. An electronic device, comprising:
a multi-layered board comprising a first board and a second board; and
an interposer disposed between the first board and the second board, wherein the interposer comprises a coaxial via configured to shield an electrical signal transmitted between the first board and the second board, wherein the coaxial via comprises:
an outer barrel of non-conductive material
an inner barrel of non-conductive material; and
a conductive barrel disposed between the outer barrel of non-conductive material and the inner barrel of non-conductive material, wherein the conductive barrel is configured to carry the electrical signal through the interposer.

2. The electronic device of claim 1, wherein the coaxial via comprises a through hole coaxial via, a blind coaxial via, or both.

3. The electronic device of claim 1, wherein the coaxial via comprises an outer metal coating enclosing the outer barrel of non-conductive material.

4. The electronic device of claim 1, wherein the outer barrel of non-conductive material enclosed by an outer metal coating comprises a diameter between 300 μm and 450 μm.

5. The electronic device of claim 1, wherein the coaxial via comprises an outer metal coating, and wherein the outer metal coating and the conductive barrel comprise copper.

6. The electronic device of claim 1, wherein the inner barrel of non-conductive material enclosed by the conductive barrel comprises a diameter between 150 μm and 250 μm.

7. The electronic device of claim 1, wherein the outer barrel of non-conductive material, the inner barrel of non-conductive material, or both comprise resin.

8. The electronic device of claim 1, wherein the electronic device comprises a computer, a handheld device, a portable phone, a wearable device, a watch, or any combination thereof, having a thickness that is defined at least in part on a thickness of the interposer, the multi-layered board, or both.

9. The electronic device of claim 1, wherein the outer barrel of non-conductive material, the inner barrel of non-conductive material, or both are associated with a dielectric constant between 2 and 3.

10. The electronic device of claim 1, wherein the multi-layered board comprises a printed circuit board.

11. A system, comprising:
a power supply;
an integrated circuit; and
a printed circuit board having a coaxial interposer that includes an outer resin layer and an inner resin layer separated by a conductive signal carrier, wherein the coaxial interposer is configured to shield a power signal transmitted from the power supply to the integrated circuit.

12. The system of claim 11, wherein the outer resin layer and the inner resin layer differ with respect to one or more dielectric properties, one or more mechanical properties, or both.

13. The system of claim 11, wherein the coaxial interposer is configured to shield a radio frequency signal transmitted between a radio frequency board and an application board associated with the printed circuit board.

14. The system of claim 11, wherein the outer resin layer is enclosed by a metal coating.

15. A coaxial interposer, comprising:
a multi-layer core; and
a coaxial via comprising a copper coating enclosing an outer barrel of resin, wherein the outer barrel of resin encloses a copper signal conduit, wherein the copper signal conduit encloses an inner barrel of resin, and wherein the coaxial via is configured to shield an electrical signal transmitted between internal layers of a printed circuit board.

16. The coaxial interposer of claim 15, wherein the coaxial interposer is associated with a constant impedance throughout a length of the coaxial via.

17. The coaxial interposer of claim 15, wherein the multi-layer core is configured to be drilled such that a first hole forms.

18. The coaxial interposer of claim 17, wherein the first hole is configured to be filled with resin to form the outer barrel of resin and the inner barrel of resin.

19. The coaxial interposer of claim 15, wherein the first hole filled with resin is configured to be drilled such that a second hole forms.

20. The coaxial interposer of claim 19, wherein the second hole comprises a wire or conductive material to form the copper signal conduit.

21. The coaxial interposer of claim 19, wherein the first hole and the second hole comprise a through hole, a blind via, or both.

22. The coaxial interposer of claim 15, wherein the coaxial interposer is associated with a loss tangent of 0.001.
